(19) United States
(12) Patent Application Publication
(10) Pub. No.: US 2014/0375196 A1
(43) Pub. Date: Dec. 25, 2014

(54) Dual Hinge Mechanism For A Bezel Of A Computer Housing

(71) Applicant: Cisco Technology, Inc., San Jose, CA (US)

(72) Inventors: Nguyen Nguyen, San Jose, CA (US); Long Dang, San Jose, CA (US)

(21) Appl. No.: 13/924,537

(22) Filed: Jun. 22, 2013

(51) Int. Cl. H05K 5/02

(52) U.S. Cl. CPC H05K 5/0239; H05K 5/0226
USPC 312/329; 29/592

(57) ABSTRACT

An apparatus includes a housing frame including an opening to facilitate insertion and removal of computer components within an interior of the housing frame, a bezel secured to the housing frame to facilitate opening and closing of the housing frame, and a hinge mechanism that facilitates pivotal movement of the bezel at different pivot locations in relation to the housing frame.

### TECHNICAL FIELD

The present disclosure relates to housings for electronic devices that include a cover or bezel detachable from the housing to facilitate access to components within the housing.

### BACKGROUND

Computer system components are typically assembled within a protective housing that includes a cover or bezel that can be opened with respect to the housing to permit access to the system components within the housing. For example, computer system components can include data storage modules, network modules, processing modules, etc., each of which includes computer components (e.g., components connected with a board, fans or other cooling components, electrical power supply structures, etc.) disposed within the housing. A plurality of computer system components can be arranged in a vertically stacked alignment within a storage rack, where a plurality of storage racks may further be provided within a storage center (e.g., for storing large amounts of data in a data warehouse, for providing communications services in a telecommunications center, etc.). The bezel for the computer housing provides both a protective feature to prevent unauthorized access to components within the computer housing as well as facilitating authorized access for opening the bezel in order to access components within the housing by personnel.

The size of certain computer component racks may render it difficult for personnel to obtain easy access within a housing depending upon the manner in which the bezel is designed to open in relation to the housing. For example, when a housing is located at an upper end of a component rack, it may be desirable for the bezel to pivotally opens in an upward direction from closed to open position in relation to the housing (so that the bezel does not impede view within the component housing), while it may be desirable for a housing located at a lower end of the component rack to have a bezel that pivotally opens in a downward direction from closed to open position in relation to the housing.

### BRIEF DESCRIPTION OF THE DRAWINGS

FIG. 1 is a view in perspective of an example embodiment of a computer component housing including a bezel with dual hinge mechanism.

FIG. 2 is a view in perspective of the computer component housing of FIG. 1 with the bezel pivoted away from the housing to expose the housing interior.

FIG. 3 is another view in perspective of the computer component housing of FIG. 1 with the bezel pivoted away from and in another orientation in relation to the housing.

FIG. 4A is a view in perspective of the main body portion for the dual hinge mechanism for the example embodiment of FIG. 1.

FIG. 4B is a partial side view of the main body portion for the dual hinge mechanism of FIG. 4A.

FIG. 5A is a view in perspective of the hinge arm for the dual hinge mechanism for the example embodiment of FIG. 1.

FIG. 5B is a side view of the hinge arm for the dual hinge mechanism of FIG. 5A.

FIG. 6 is a view of a hinge structure for the dual hinge mechanism for the example embodiment of FIG. 1.

FIG. 7A is a side view in elevation of the computer component housing of FIG. 1 with the bezel pivoted away from the housing frame toward a lower position of the component housing.

FIG. 7B is a side view in elevation of the computer component housing of FIG. 1 with the bezel pivoted away from the housing frame toward an upper position of the component housing.

### DESCRIPTION OF EXAMPLE EMBODIMENTS

### Overview

An apparatus comprises a housing frame including an opening to facilitate insertion and removal of computer components within an interior of the housing frame, a bezel secured to the housing frame to facilitate opening and closing of the housing frame, and a hinge mechanism that facilitates pivotal movement of the bezel at different pivot locations in relation to the housing frame.

### Example Embodiments

A bezel for a computer component housing includes a dual hinge mechanism or structure that connects the bezel with the housing. The dual hinge mechanism facilitates opening of housing to expose the housing interior by pivoting the bezel away from the housing in a plurality of directions. Thus, different orientations of the bezel in relation to the housing are enabled, which allows easier user access to the housing interior depending upon the position of the housing in relation to a user.

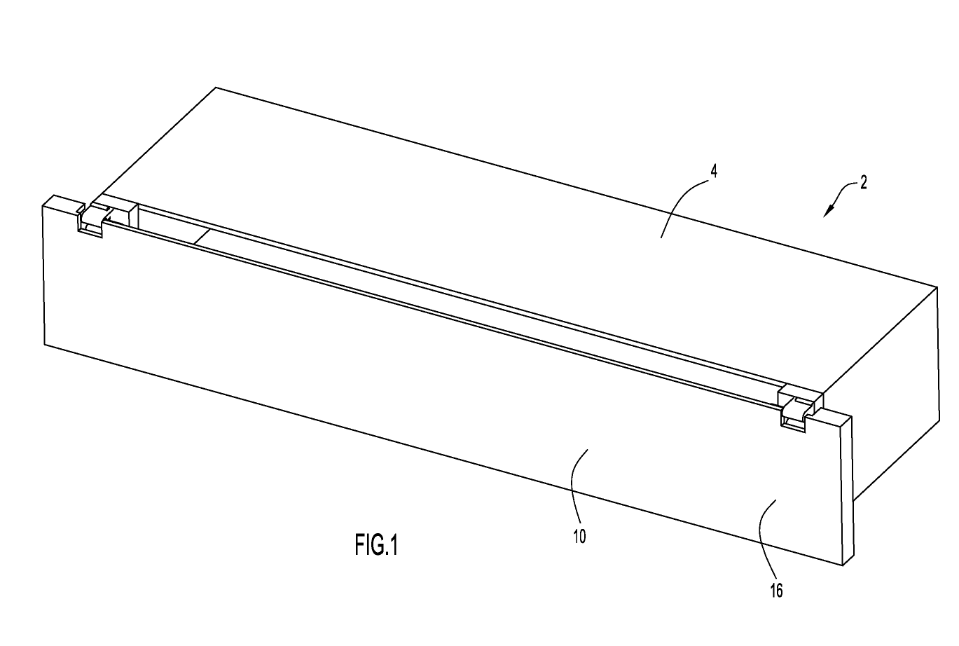

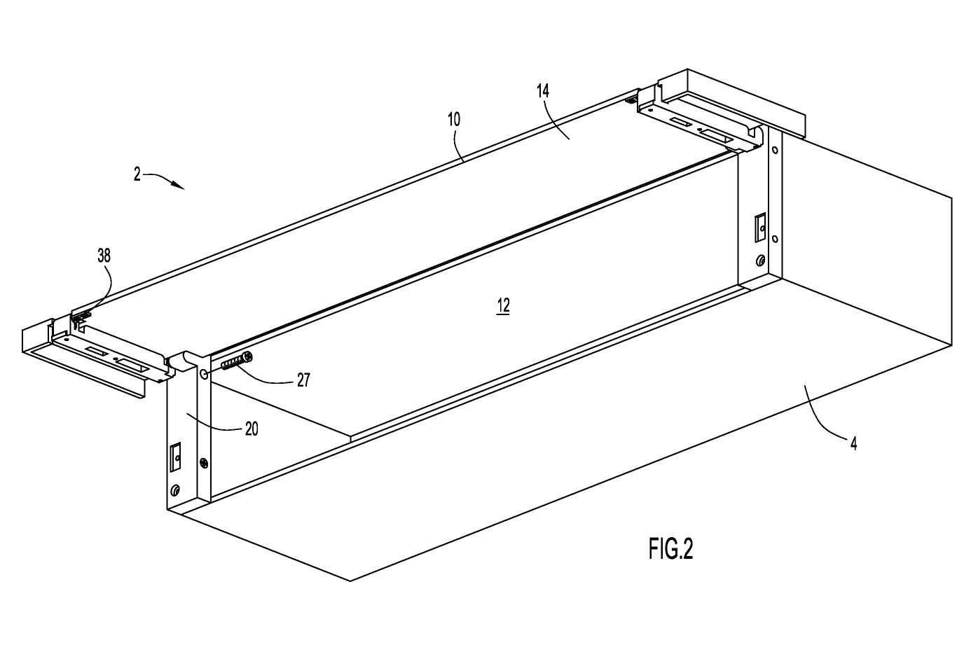

Referring to FIGS. 1 and 2, an example embodiment of a computer component housing 2 is depicted including a generally rectangular shaped housing frame 4 having a hollow interior 12. The housing frame 4 includes five generally planar panels connected with each other to form the exterior side walls of the housing 2, where one side of the frame 4 is at least partially open to expose the interior 12. A generally planar shaped bezel 10 pivotally connects with the housing frame 4, in a manner as described herein, to facilitate closure of the housing 2 (as depicted in FIG. 1) and also opening of the housing 2 (e.g., as depicted in FIG. 2) to expose the housing interior 12 to facilitate access to computer components disposed within the housing interior 12.

Each of the exterior panels of the housing frame 4 and the bezel 10 can be constructed of any suitable metal or other sturdy materials capable of supporting and protecting computer components provided and secured within the housing interior 12. It is noted that the housing interior 12 can include any suitable number and types of computer components (e.g., circuit boards including processors, memories, wiring circuits, and any other suitable components) as well as fans, power supply components, etc. The housing interior 12 can further include any suitable support structure to support the components (e.g., clips, supports, pegs/notches or any other suitable fastening structures).

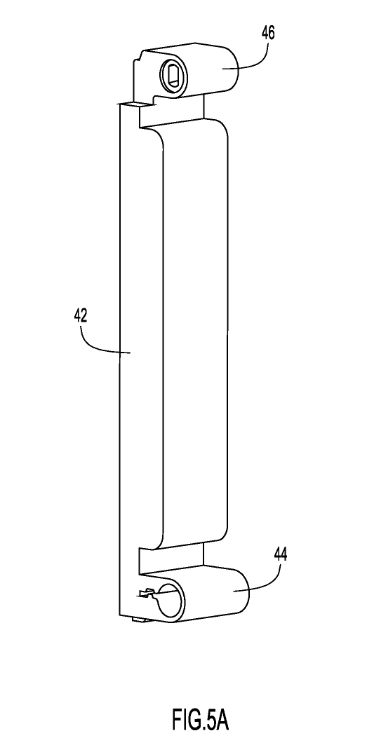

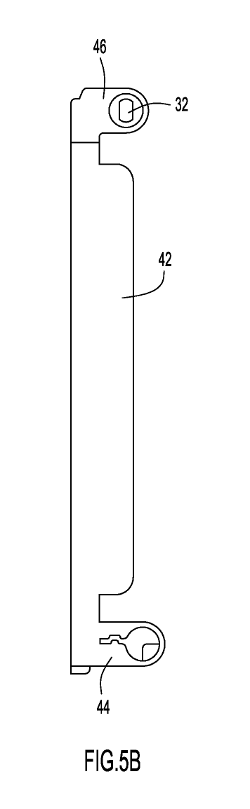

A dual hinge mechanism 20 includes portions that connect with each of the housing frame 4 and the bezel 10 to facilitate pivotal movement of the bezel 10 along a plurality of pivot points with respect to the housing frame 4 to facilitate opening of the housing 2 to permit access to the housing interior 12. Each portion of the dual hinge mechanism 20 is constructed of one or more suitable materials, e.g., metal (e.g., a zinc alloy). Referring to FIGS. 2, 3, 4A, 4B, 5A and 5B, the dual hinge mechanism 20 includes a pair of hinge members located near the lower edge and near opposing corners of the bezel 10. Each hinge member of the mechanism 20 includes a main body portion 22 and a hinge arm 42 that pivotally connects at a first hinge end 44 with hinge structure at a rear surface 14 near the lower edge and corresponding corner of the bezel 10 to facilitate pivotal movement of the bezel 10 in relation to each main body portion 22 and hinge arm 42 when the dual hinge mechanism 20 is connected with the frame 4 and the bezel 10. Each hinge arm 42 further connects at a second hinge end 46 with hinge structure at a hinge end 24 of the main body portion 22.

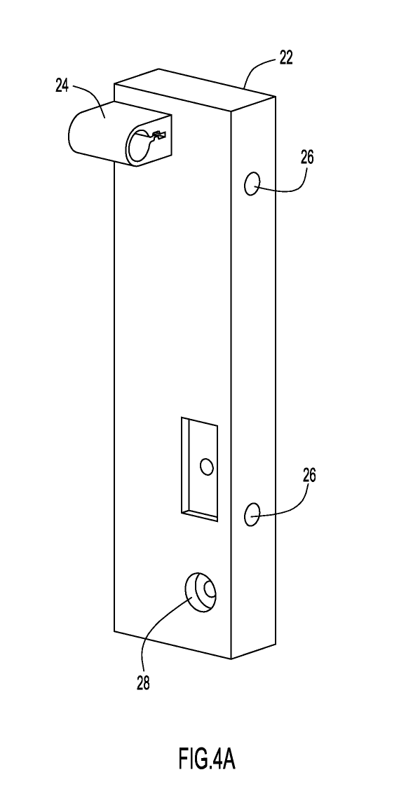

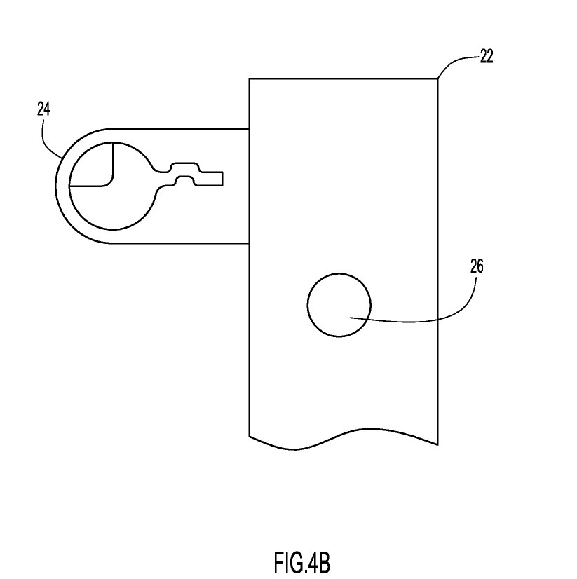

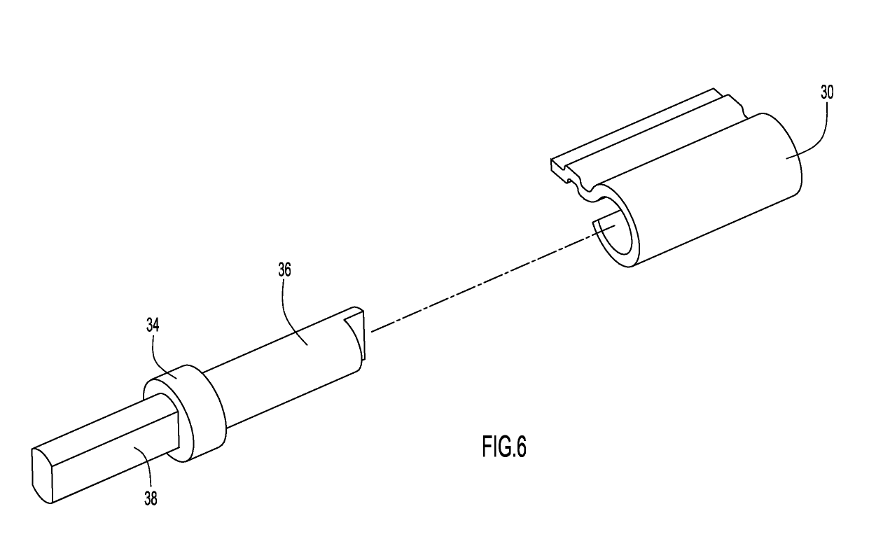

The hinge structure that pivotally connects the first and second hinge ends 44, 46 of each hinge arm 42 with the bezel 10 and the main body portion 22 is illustrated in FIGS. 4A, 4B, 5A, 5B and 6. The hinge structure includes a pin receiver member 30 with a round opening configured to slidably receive and frictionally retain a corresponding rounded end 36 of a hinge pin 34. The dimensions of the opening for the pin receiver member 30 and the rounded end 36 of the hinge pin 34 are designed to permit rotation of the hinge pin 34 when its rounded end 36 is fit within member 30. The hinge pin 34 further includes, generally rectangular or faceted end 38 that fits within a corresponding rectangular or faceted slot of the hinge structure. When the hinge pin 34 is properly inserted within each of the pin receiver member 30 and the faceted slot of the hinge structure, the hinge structure permits rotation between the hinge pin 34 and the pin receiver member 30 while preventing any rotation between the pin 34 and the faceted slot.

The first hinge end 44 of each hinge arm 42 includes a housing with an opening configured to receive a pin receiver member 30 (where the pin receiver member 30 is prevented from rotating within the housing opening of the first hinge end 44). The rear surface 14 of the bezel 10 includes a suitable securing mechanism to connect with the end 38 of a hinge pin 34.

The first hinge end 44 of each hinge arm 42 is connected to the rear surface 14 of the bezel 10 near a corner location of the bezel by connecting the end 38 of the hinge pin 34 with a suitable securing mechanism located at the bezel rear surface 14 and inserting the end 36 of the hinge pin 34 into the opening of the pin receiver member 30 at the first hinge end 44. In an example embodiment, the bezel rear surface 14 near the bezel corner location includes a plurality of screw holes configured to receive screws attached with the end 38 of the hinge pin 34 to facilitate fastening of the hinge pin 34 to the bezel 10.

After connecting the first hinge end 44 with hinge pin 34 to at the corner location of the bezel rear surface 14, the rounded end 36 can rotate within member 30 while the faceted end 38 is prevented from such rotation (since end 38 is secured to the bezel rear surface 14), thus permitting pivotal movement between each hinge arm 42 at its first hinge end 44 and the bezel 10.

The second hinge end 46 of each hinge arm 42 connects with the hinge end 24 of the main body portion 22 by insertion of a faceted end 38 of a hinge pin 34 into a faceted slot 32 located at the second hinge end 46. The rounded end 36 of the hinge pin 34 is inserted into the rounded opening of a pin receiver member 30 connected at the hinge end 24 of the main body portion 22 (e.g., by fitting the member 30 within an opening at the hinge end 24), where the pin receiver member 30 extends transversely in relation to a lengthwise orientation of the main body portion 22, and member 30 is prevented from rotating at its connection at the hinge end 24. The hinge structure provided at the second hinge end 46 of each hinge arm 42 and the hinge end 24 of each corresponding main body can be further configured to facilitate a friction fit or snap fit of the second hinge end 46 with the hinge end 24, with hinge pin 34 connected within receiver member 30 and slot 32 so as to facilitate a locking connection between the hinge arm 42 and the main body 22 while permitting pivotal movement between hinge arm 42 and main body 22 at their hinge ends 46, 24 (via rotation of the rounded end 36 of the hinge pin 34 in the member 30 without rotation of end 38 of the hinge pin 34 within the slot 32).

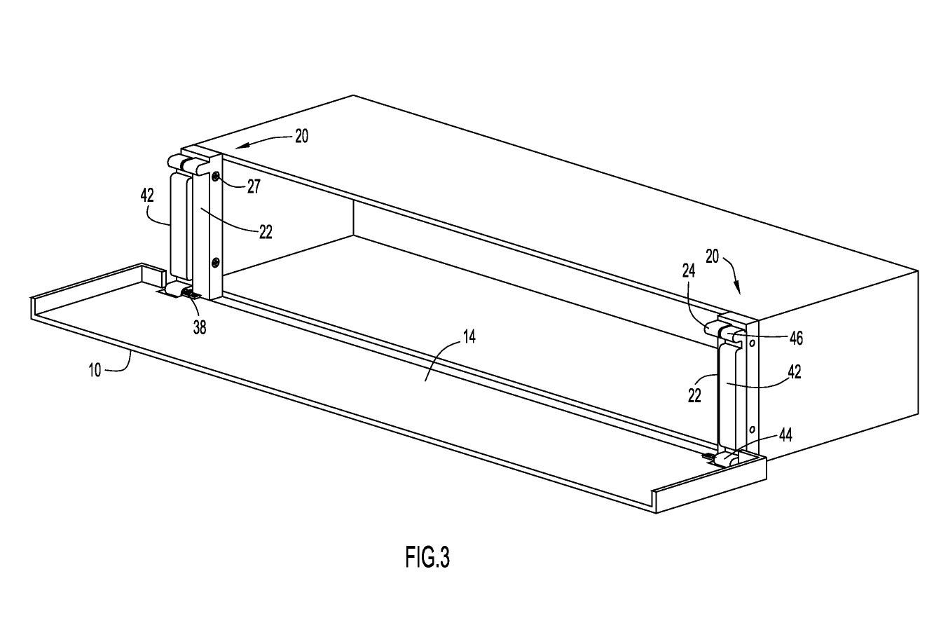

As indicated, e.g., in FIG. 3, each hinge member is designed as a “mirror image” of the other, where the hinge arm 42 for each hinge member is disposed closer to a corresponding corner of the bezel 10 in relation to the member 30 at the hinge end 24. Thus, each hinge arm 42 may be considered as having a “left hand” or “right hand” configuration that connects with a corresponding left or right side of the rear surface 14 of the bezel 10 as well as a corresponding main body 22 having a corresponding “left hand” or “right hand” configuration.

Each main body portion 22 further includes one or more openings or slots 26 extending through the main body portion 22 (e.g., in a direction that is parallel or generally corresponds with a direction of the round opening for the receiver member 30 provided at the hinge end 24). The slots 26 are provided to facilitate connection of each main body portion 22 to corresponding structure of the housing frame 4 (e.g., utilizing screws or any other suitable fasteners 27, as indicated at FIG. 2) such that each main body portion 22 is connected at an opposing frame edge that defines the opening within the frame 4 to expose the housing interior 12.

Each main body portion 22 includes at least one recess 28 disposed on a surface of the main body portion 22 that faces toward the corresponding hinge arm 42. Each recess 28 can be configured to receive and retain a magnet that magnetically attracts the corresponding hinge arm 42 (in example embodiments in which the hinge arm is constructed of a suitable metallic material, e.g., a magnetic zinc alloy). In the configurations for the hinge mechanism 20 as depicted in FIGS. 2, 3 and 7A, the use of one or more magnets secured to each main body portion 22 at locations underlying the corresponding hinge arms 42 can provide a magnetic attraction and holding force between main body portion 22 and hinge arm 42 so as to keep both components engaged during pivotal movement of the bezel 10 at the first hinge ends 44 of the hinge arms 42. The magnetic holding force can be overcome by, e.g., pivoting each hinge arm 42 away from the corresponding main body portion 22 at the second hinge end 46.

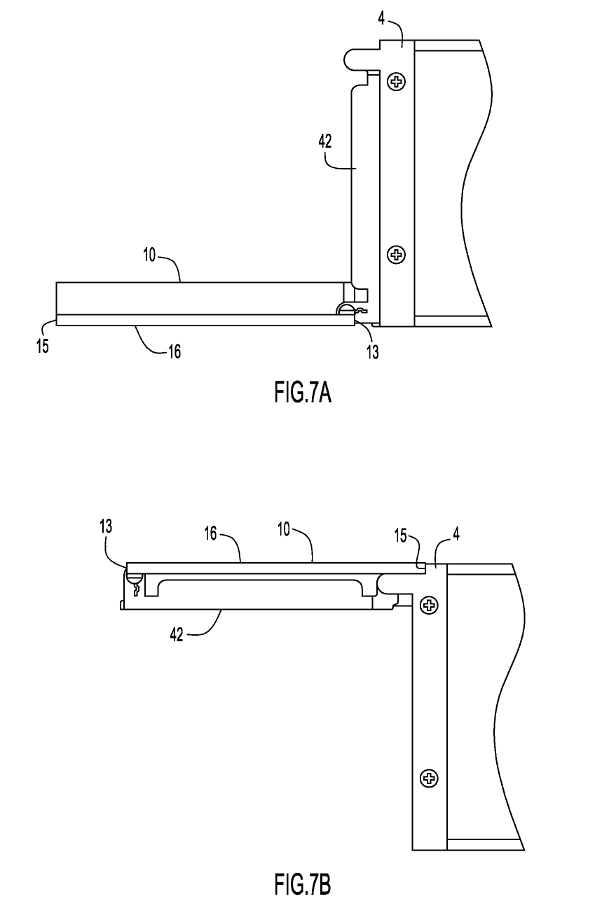

Operation of the computer component housing 2 using the dual hinge mechanism 20 is now described with reference to the drawings (in particular, FIGS. 7A and 7B). The bezel 10 is initially in a position as depicted in FIG. 1, in which the housing 2 is closed and the bezel 10 is engaged against the housing frame 4 to prevent access to the housing interior 12 and a front surface 16 of the bezel (which opposes the bezel rear surface 14) defines one side surface of the housing 2. In a scenario in which it is desired to open the bezel 10 to a lower position in relation to the housing frame 4 (as depicted in FIG. 7A), an upper side or edge 13 of the bezel 10 can be gripped by a user to pull the bezel 10 away from the frame 4 by pivoting the first hinge ends 44 of the hinge arms 42 in relation to the main body portions 22 (where each pivot pin 34, which is in a fixed orientation in relation to the corresponding hinge structure 18 of the frame 4, rotates in relation to the pin receiver member 30 secured within the corresponding hinge arm 42). The magnetic attraction between each hinge arm 42 and one or more magnets disposed within the corresponding main body portion 22 prevents or substantially limits movement of the hinge arms 42 from engagement with their corresponding main body portions 22 during pivotal movement of the bezel 20 from the initial closed position (FIG. 1) to a housing open position as depicted in FIG. 7A. The bezel 10 can be pivotally moved from this open position back to the closed position when it is desired to close the housing 2.

Utilizing the dual hinge mechanism 20, the bezel can be pivoted at a different pivot point location away from the housing frame 4, as depicted in FIG. 7B, by gripping a lower side or edge 15 of the bezel 10 and moving the bezel away from the housing frame 4. In this scenario, the second hinge end 46 of each hinge arm 42 pivots in relation to the hinge end 24 of the corresponding main body portion 22 (where each pivot pin 34, which is in a fixed orientation in relation to the slot 34 at the corresponding second hinge end 46, rotates in relation to the pin receiver member 30 secured at the hinge end 24 of the corresponding main body portion 22). The magnetic attraction force between the magnets of the main body portions 22 and the hinge arms 42 is overcome, and the hinge arms 42 travel with the bezel 10 during movement of the bezel lower side or edge 15 away from and to an upward position in relation to the housing frame 4. The bezel 10 can be pivoted back to a closed position (FIG. 1) when it is desired to close the housing 2.

Thus, the dual hinge mechanism facilitates pivotal movement of the bezel at a plurality of pivot points in relation to the housing frame in order to orient the bezel at different positions to expose the housing interior. This in turn facilitates easier access to the housing interior when the component housing is placed at various different elevations within a component rack or any other support structure.

While the example embodiment depicting a dual hinge mechanism is in relation to a cover or bezel moving to different vertical orientations in relation to a housing frame, it is noted the other embodiments are also possible in which the bezel can be pivotally moved at different pivot points to orient the bezel in a variety of different vertical and/or horizontal positions in relation to the frame housing. Further, any suitable fastening materials can be utilized to secure the main body portions to the frame, and any suitable hinge structures can be utilized to facilitate pivotal movement of the bezel in relation to a first pivot end of one or more pivot arms and pivotal movement of a second pivot end of the one or more pivot arms in relation to one or more main body portions. Any suitable number of pivot arms and/or main body portions can also be utilized to achieve pivoting of the bezel at a variety of different orientations and utilizing different pivot point locations in relation to the housing frame.

The above description is intended by way of example only.

What is claimed is:

1. An apparatus comprising:
a housing frame including an opening to facilitate insertion and removal of computer components within an interior of the housing frame;
a bezel secured to the housing frame to facilitate opening and closing of the housing frame; and
a hinge mechanism that facilitates pivotal movement of the bezel at a plurality of different pivot locations in relation to the housing frame.

2. The apparatus of claim 1, wherein the bezel includes a first edge and a second edge that opposes the first edge, and the hinge mechanism facilitates pivotal movement of the first edge of the bezel away from the housing frame via a first pivot location proximate the second edge, and the hinge mechanism further facilitates pivotal movement of the second edge of the bezel away from the housing frame via a second pivot location proximate the first edge.

3. The apparatus of claim 2, wherein pivotal movement of the bezel via the first pivot location moves the first edge of the bezel to a lower position in relation to the housing frame, and pivotal movement of the bezel via the second pivot location moves the second edge of the bezel to a higher position in relation to the housing frame.

4. The apparatus of claim 1, wherein the hinge mechanism comprises:
a hinge arm that connects at a first end to the bezel to facilitate pivotal movement of the bezel in relation to the hinge arm and housing frame at the hinge arm first end.

5. The apparatus of claim 4, wherein the hinge arm further connects at a second end to the housing frame to facilitate pivotal movement of the hinge arm and bezel in relation to the housing frame at the hinge arm second end.

6. The apparatus of claim 5, wherein the hinge mechanism further comprises:
a main body portion secured to the housing frame;
wherein the second end of the hinge arm pivotally connects with the main body portion.

7. The apparatus of claim 6, wherein the main body portion includes a magnetic structure that magnetically attracts the hinge arm to a surface of the main body portion.

8. The apparatus of claim 6, wherein the hinge mechanism further comprises a pair of hinge arms and a pair of main body portions, each hinge arm being pivotally connected with a corresponding main body portion.

9. The apparatus of claim 8, wherein a connection with one hinge arm with its corresponding main body portion of the pair forms a first hinge connector that is a mirror image of a second hinge connector formed by the other hinge arm and the other main body portion of the pair.

10. The apparatus of claim 9, wherein the first hinge connector connects with the bezel near a first corner of the bezel and the second hinge connector connects with the bezel near a second corner of the bezel.

11. A method comprising:
providing a housing frame including an opening to facilitate insertion and removal of computer components within an interior of the housing frame;
providing a bezel secured to the housing frame to facilitate opening and closing of the housing frame; and
opening the housing frame by pivotally moving the bezel in relation to the housing frame via a hinge mechanism, wherein the hinge mechanism facilitates pivotal movement of the bezel at a plurality of different pivot locations in relation to the housing frame.

12. The method of claim 11, wherein the bezel includes a first edge and a second edge that opposes the first edge, and the opening the housing frame further comprises:
via the hinge mechanism, pivotally moving the first edge of the bezel away from the housing frame via a first pivot location proximate the second edge; and
via the hinge mechanism, pivotally moving the second edge of the bezel away from the housing frame via a second pivot location proximate the first edge.

13. The method of claim 12, wherein pivotal movement of the bezel via the first pivot location moves the first edge of the bezel to a lower position in relation to the housing frame, and pivotal movement of the bezel via the second pivot location moves the second edge of the bezel to a higher position in relation to the housing frame.

14. The method of claim 11, wherein the hinge mechanism comprises a hinge arm that connects at a first end to the bezel, and the opening the housing frame further comprises:
pivotally moving the bezel in relation to the hinge arm and housing frame at the hinge arm first end.

15. The method of claim 14, wherein the hinge arm further connects at a second end to the housing frame, and the opening the housing frame further comprises:
pivotally moving the hinge arm and bezel in relation to the housing frame at the hinge arm second end.

16. The method of claim 15, wherein the hinge mechanism further comprises a main body portion secured to the housing frame, and pivotal movement of the hinge arm and bezel in relation to the housing frame at the hinge arm second end further comprises:
pivotally moving the second end of the hinge arm in relation to the main body portion.

17. The method of claim 16, wherein the method further comprises:
facilitating magnetic attraction of the hinge arm to a surface of the main body portion via a magnetic structure of the main body portion.

18. The method of claim 16, wherein the hinge mechanism further comprises a pair of hinge arms and a pair of main body portions, each hinge arm being pivotally movable in relation to a corresponding main body portion.

19. The method of claim 18, wherein a connection with one hinge arm with its corresponding main body portion of the pair forms a first hinge connector that is a mirror image of a second hinge connector formed by the other hinge arm and the other main body portion of the pair.

20. The method of claim 19, wherein the first hinge connector connects with the bezel near a first corner of the bezel and the second hinge connector connects with the bezel near a second corner of the bezel.
